(19) United States
(12) Patent Application Publication
(10) Pub. No.: US 2002/0043983 A1
(43) Pub. Date: Apr. 18, 2002

(54) Chip-testing socket using surface mount techinology

(76) Inventor: Wei-Jen Cheng, Shindian City (TW)

Correspondence Address: RABIN & CHAMPAGNE, PC, 1101 14TH STREET, NW, SUITE 500, WASHINGTON, DC, 20005, US

(21) Appl. No.: 09/982,847

(22) Filed: Oct. 22, 2001

(30) Foreign Application Priority Data
Oct. 18, 2000 (TW) 89121876

(51) Int. Cl. G01R 31/02

(52) U.S. Cl. 324/755

(57) ABSTRACT

A chip-testing socket using surface mount technology is used for holding a ball grid array (BGA) chip to be tested. The chip-testing socket includes a base and a fixing portion. The base has a number of windows for positioning to a circuit board, and a number of elastic pin probes electrically connected to the circuit board. The base could be disposed on the circuit board by using surface mount technology. The fixing portion is applied to fix the chip on the base wherein the fixing portion can be disposed to the base in a removable way.

### BACKGROUND OF THE INVENTION

This application incorporates by reference Taiwanese application Ser. No. 089121876, filed on Oct. 18, 2000.

1. Field of the Invention

The invention relates in general to a chip-testing socket, and more particularly to a chip-testing socket using surface mount technology (SMT) for functional test of a chip.

2. Description of the Related Art

Generally, after a chip has been manufactured, the chip should be tested to ensure the accuracy of the chip function. In the traditional method of testing, it begins with fixing a chip-testing socket for chip testing to a circuit board, then placing the chip to be tested in the chip-testing socket. Due to the electrically connection between the chip and the circuit board, the function of the chip is tested by applying testing signals through the circuit board.

A ball grid array (BGA) chip uses arrayed bump electrodes rather than pins for electrical connection, and the BGA chip could be fixed on the pads of the circuit board by using surface mount technology. However, the traditional chip-testing socket for testing BGA chip uses pin probes of dual in-line package (DIP). Therefore, the chip-testing socket could not be fixed on the pads of the circuit board by using surface mount technology as the BGA chip.

Consequently, during the testing of the BGA chip, which is mounted on the circuit board, the circuit board should be re-designed to be adapted to the chip-testing socket having DIP pin probes. The re-designed circuit board must have holes for fixing the chip-testing socket having DIP pin probes. However, the circuit board having pads need only four layers, and the re-designed circuit board having holes need six layers instead. Thus, re-layout is necessary to produce the re-designed circuit board having holes, which increases the cost of chip testing, and delays production. Furthermore, the electrical characteristic of the re-layout circuit board is changed compared to the original circuit board, and the accuracy of measured signal decreases because the impedance of the re-layout circuit board is difficult to control.

In order to solve the above-mentioned problems, another traditional chip-testing socket that could be fixed on the circuit board by using surface mount technology is implemented. However, the area of the bottom surface of this traditional chip-testing socket is larger than the socket disposing area on the circuit board, so it is very difficult to position the chip-testing socket. Because it is difficult to align the pin probes to the corresponding pads on the circuit board, the failure rate of fixing the chip-testing socket to the circuit board is high. Besides, the ends of the pin probes of the chip-testing socket may not be of the same plane. Therefore, electrical contact error may occur when the chip-testing socket is fixed on the circuit board, which influences the accuracy of chip testing and the transmission of the electrical signals between the chip-testing socket and the circuit board.

### SUMMARY OF THE INVENTION

It is therefore an object of the invention to provide a chip-testing socket using surface mount technology. The chip-testing socket has several windows for positioning the base, and high positioning accuracy could be achieved easily. Besides, the ends of the chip-testing socket not being of the same plane can be avoided to prevent contact error. Therefore, the accuracy of chip testing when applying the chip-testing socket is improved substantially owing to the decrease of the failure rate of electrical connection between the ship-testing socket and the circuit board. Moreover, the chip-testing socket of the invention reduces the cost and the time of chip testing.

It is an object of the invention to provide a chip-testing socket using surface mount technology for holding a ball grid array (BGA) chip to be tested. The chip-testing socket includes a base and a fixing portion. The base has a number of windows for positioning to a circuit board, and a number of pin probes electrically connected to the circuit board. The base could be disposed on the circuit board by using surface mount technology. The fixing portion is applied for fixing the chip on the base wherein the fixing portion could be disposed to the base in a removable way.

It is another object of the invention to provide a chip-testing socket using surface mount technology for holding a ball grid array (BGA) chip to be tested. The chip-testing socket includes a base. The base has a number of windows for positioning to a circuit board, and a number of elastic pin probes electrically connected to the circuit board, wherein the base could be disposed on the circuit board by using surface mount technology.

It is further another object of the invention to provide an elastic pin probe which is disposed in a bass for holding a chip. The elastic pin probe includes an upper segment and a lower segment. The upper segment has a concave pin probe tip and a stick-like part. The concave pin probe tip brings perfect connection between the elastic pin probe and a convex electrode of the chip, and the stick-like part connects to the concave pin probe tip. The upper segment is put into the lower segment and is separated from the lower segment by an elastomer.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIGS. 1A˜1C illustrate the base of the chip-testing socket using surface mount technology according to the embodiment of the invention;

FIG. 2A illustrates a chip-testing socket having a buckle-type fixing portion;

FIG. 3 illustrates a perspective view of the pin probe in FIGS. 1A˜1C;

FIGS. 4A˜4D illustrate the process of using the chip-testing socket having buckle-type fixing portion according to the embodiment of the invention.

### DESCRIPTION OF THE PREFERRED EMBODIMENT

The chip-testing socket using surface mount technology (SMT) of the invention is utilized for holding a BGA chip to be tested. The chip could be fixed on a circuit board by using surface mount technology. The chip-testing socket of the invention includes a base and a fixing portion. The base has a number of pin probes electrically connected to the circuit board and has several windows for positioning to the circuit board. The fixing portion is applied to fix the chip on the base. Besides, the base could be disposed on the circuit board by using surface mount technology, and the fixing portion could be disposed to the base in a removable way. Different types of fixing portions could be designed according to different requirements for testing convenience. The pin probes could be elastic pin probes.

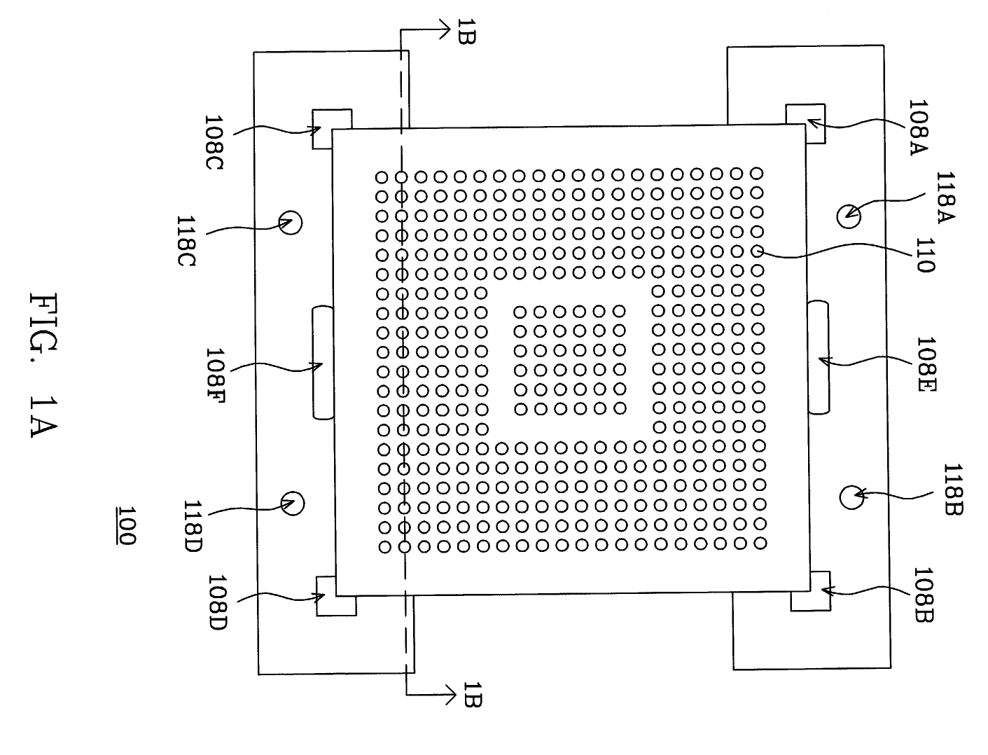

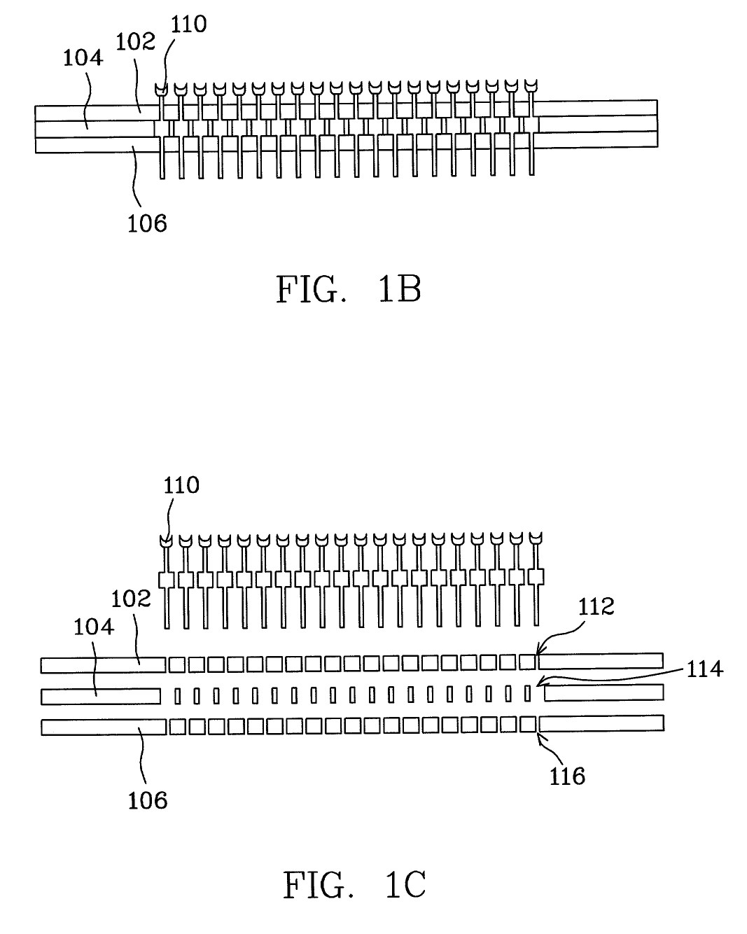

Referring to FIGS. 1A˜1C, the base of the chip-testing socket using surface mount technology according to the embodiment of the invention is illustrated. FIG. 1A is a top view of the base. FIG. 1B is a cross-sectional view of the base shown in FIG. 1A taken along section line 1B-1B. FIG. 1C is a cross-sectional view according to FIG. 1B with the pin probes separated.

The Base 100 has an upper-layer 102, a middle-layer 104, and a lower-layer 106. The upper-layer 102, the middle-layer 104, and a lower-layer 106 have several windows, for example, comer windows 108A, 108B, 108C, and 108D, and side windows 108E and 108F. These windows 108 are employed to position the base to the circuit board. Namely, when a user tries to fix the base 100 on circuit board, the user can aim at the region line that indicates the location for disposing the chip on the circuit board through the windows 108. Then, the user can dispose the base 100 on the right location on the circuit board. Therefore, accurate positioning is achieved.

The base 100 further has a number of pin probes 110. These pin probes are arranged in the same way as the balls of the BGA chip for electrically connecting the chip to the circuit board. Then, upper-layer holes 112, middle-layer holes 114, and lower-middle holes 116 in the upper-layer 102, middle-layer 104, and lower-middle 106 respectively are employed for holding the pin probes in the base 100.

Besides, the base 100 has several screw holes, including screw holes 118A, 118B, 118C, and 118D. The fixing portion (not shown in FIG. 1A-1C) is fixed on the base 100 by inserting and tightening screws in the screw holes 11 8A, 118B, 118C, and 118D.

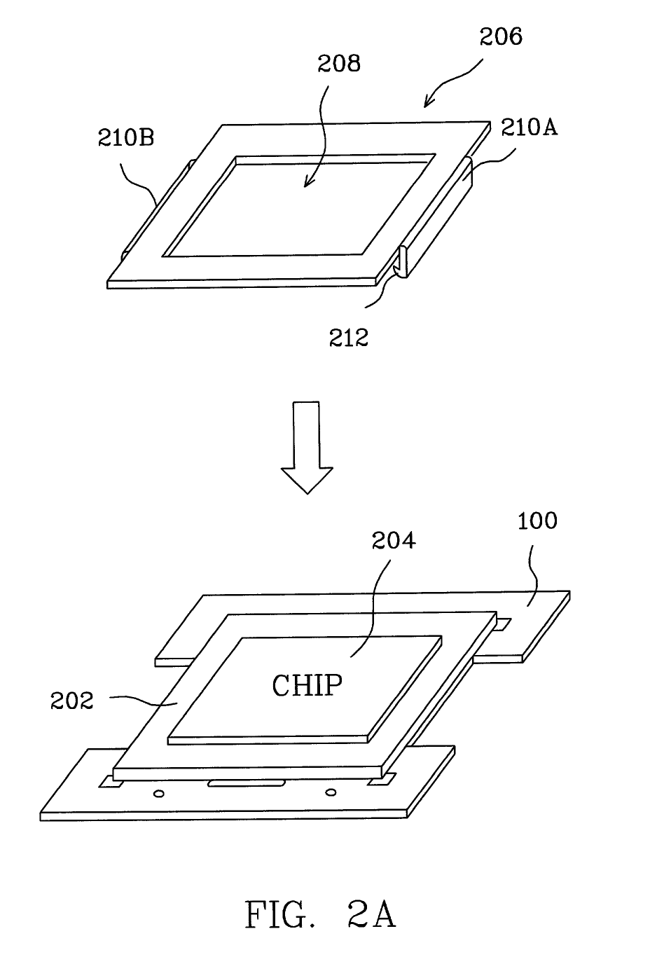

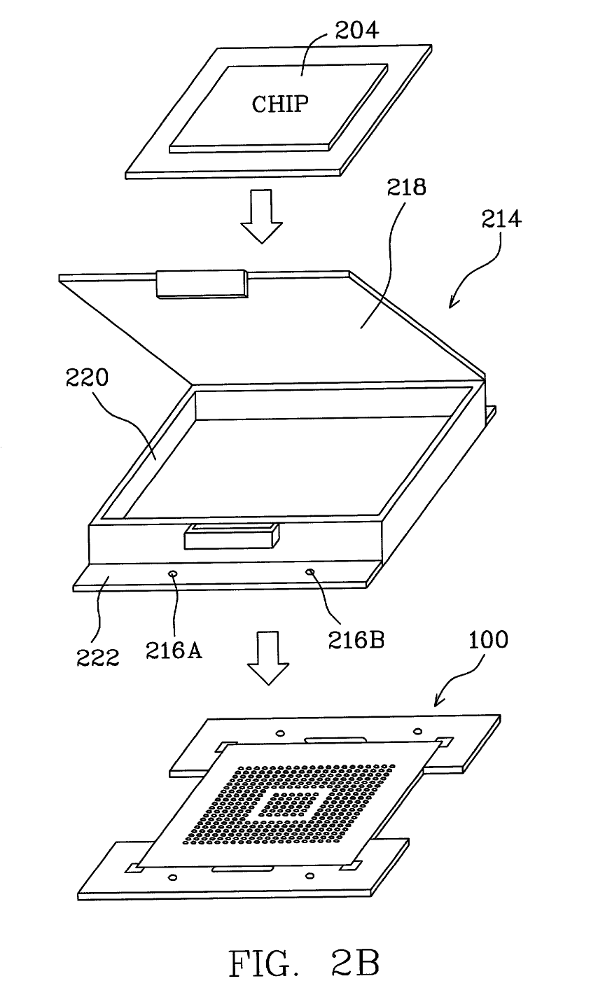

Referring to FIG. 2A, a chip-testing socket having a buckle-type fixing portion is illustrated. After the chip 204 is disposed on the base 100, the chip 204 is fixed on the base 100 by using the buckle-type fixing portion 206. The buckle-type fixing portion 206 has an opening 208 and a pair of elastic side boards with buckles 2100A and 210B. During the process of pressing downwards the buckle-type fixing portion 206 toward the base 100, the pair of elastic side boards 210A and 210B bend outward until the buckles 212 hook up a bottom surface of the base 110.

Referring to FIG. 2B, a chip-testing socket having a cover-type fixing portion is shown. The cover-type fixing portion 214 could be fixed on the base 100 by tightening screws (not shown in FIG. 2B) into screw holes 216A and 216B, for example. After that, the chip 204 is placed within the cover-type fixing portion 214, and then the chip 204 is tested. The above-mentioned cover-type fixing portion includes a cover 218 and a fixing portion body 220, and the cover 218 connects to the fixing portion body 220 rotationally. The chip 204 could be held within the cavity of the fixing portion body 220, and thus the chip 204 connects to the base 100 electrically after the fixing portion body 220 is fixed on the base 100. In addition, screw holes 216A and 216B are located on a lateral board 222 which extend outward horizontally beside the bottom surface of the cover-type fixing portion 214.

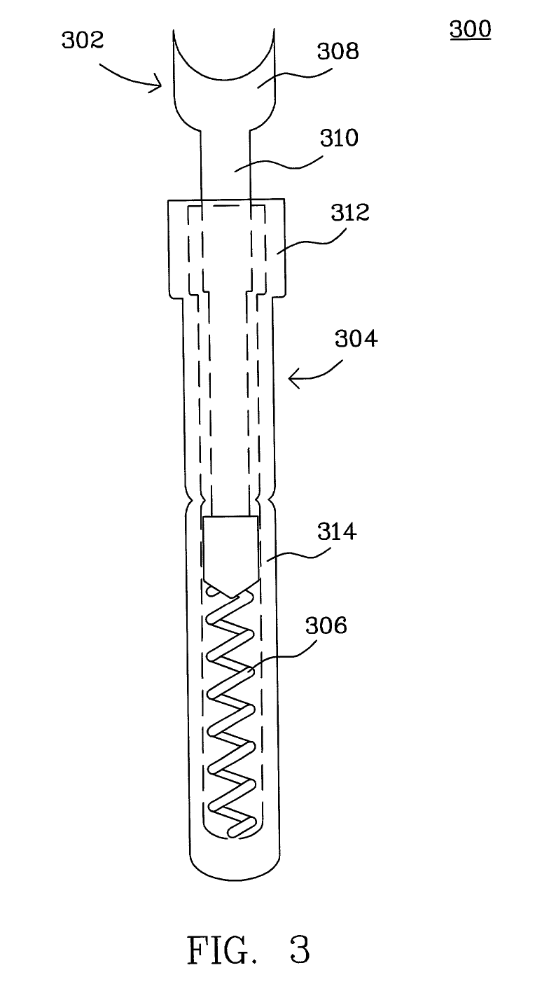

Referring to FIG. 3, a perspective view of the pin probe in FIGS. 1A˜1C is illustrated. The pin probe employed in the chip-testing socket of the invention could be an elastic pin probe 300. The elastic pin probe 300 have an upper segment 302 and a lower segment 304. The upper segment 302 is housed into the lower segment 304, and is separated from the lower segment 304 by an elastomer (for example, a spring 306). Therefore, the length of the elastic pin probe 300 varies depending on the force applied upon the elastic pin probe 300.

The upper segment 302 has a concave pin probe tip 308 and a stick-like part 310. The concave pin probe tip 308 brings perfect connection between the elastic pin probe 300 and the convex electrode of the tested BGA chip 204. The stick-like part 310 connects to the concave pin probe tip 308. The pin probe lower segment 304 has a ring projecting part 312 and a tube part 314 which connects to the ring projecting part 312. When the ring projecting part 312 is embedded in the hole 114 of the middle-layer 104, the elastic pin probe 300 could be fixed in the base 100. Besides, the tube part 314 is employed to engage the stick-like part 310 and the spring 306. The spring 306 is between the stick-like part 310 and the tube part 314 and plays a role as a buffer, and the spring 306 gets shorter when the elastic pin probe 300 is pressed.

Referring to FIGS. 1B and IC, the method to fix the elastic pin probes 300 in the base 100 is described below. The diameter of the stick-like part 310 is smaller than the ring projecting part, and the diameter of the ring projecting part 312 is larger than the tube part 314. The upper-layer hole 112 and the middle-layer hole 114 are of different diameters, and the middle-layer hole 114 and the lower-layer hole 116 are of different diameters, too. Furthermore, the diameters of the upper-layer hole 112, middle-layer hole 114, and lower-layer hole 116 are slightly larger than the diameters of the stick-like part 310, the ring projecting part 312, and the tube part 314 respectively. After the tube part 314, the ring projecting part 312, and the stick-like part 310 are inserted in the lower-layer hole 116, the middle-layer hole 114, and the upper-layer hole 112 respectively, the elastic pin probes 300 is embedded in the base 100.

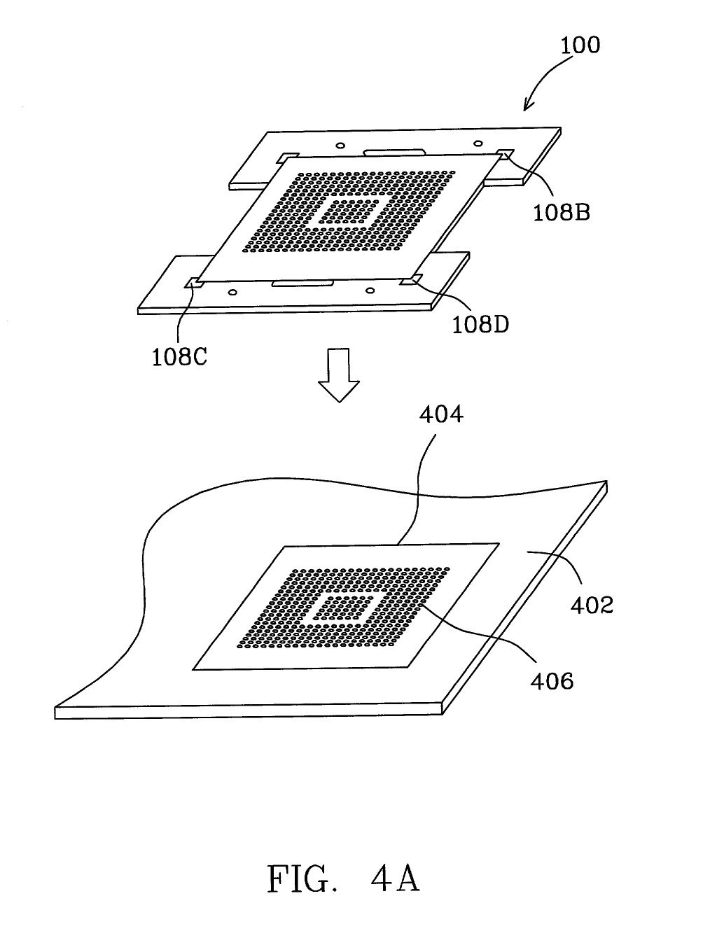

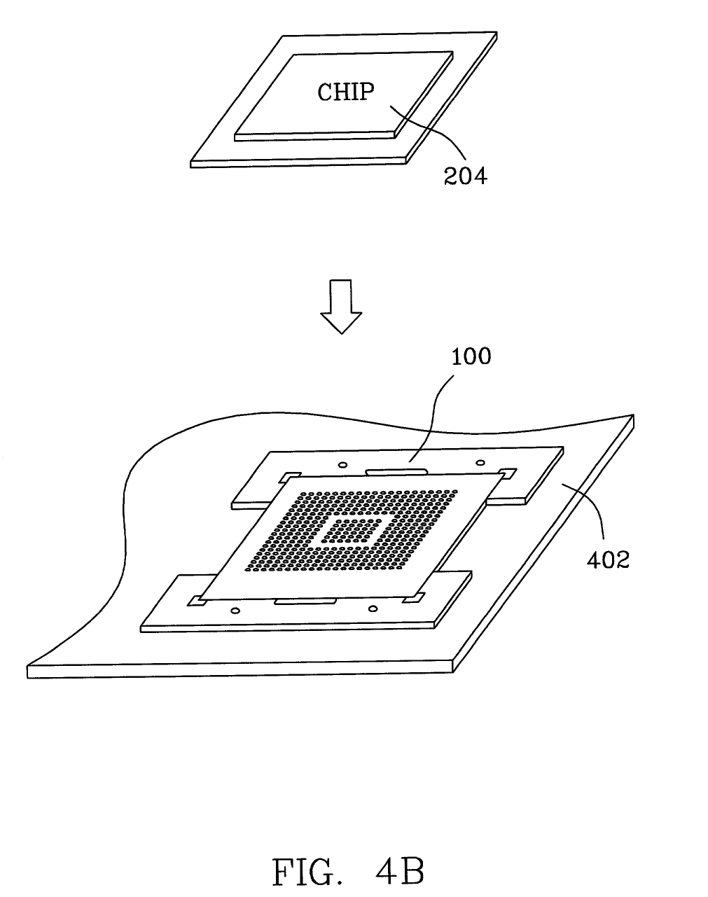

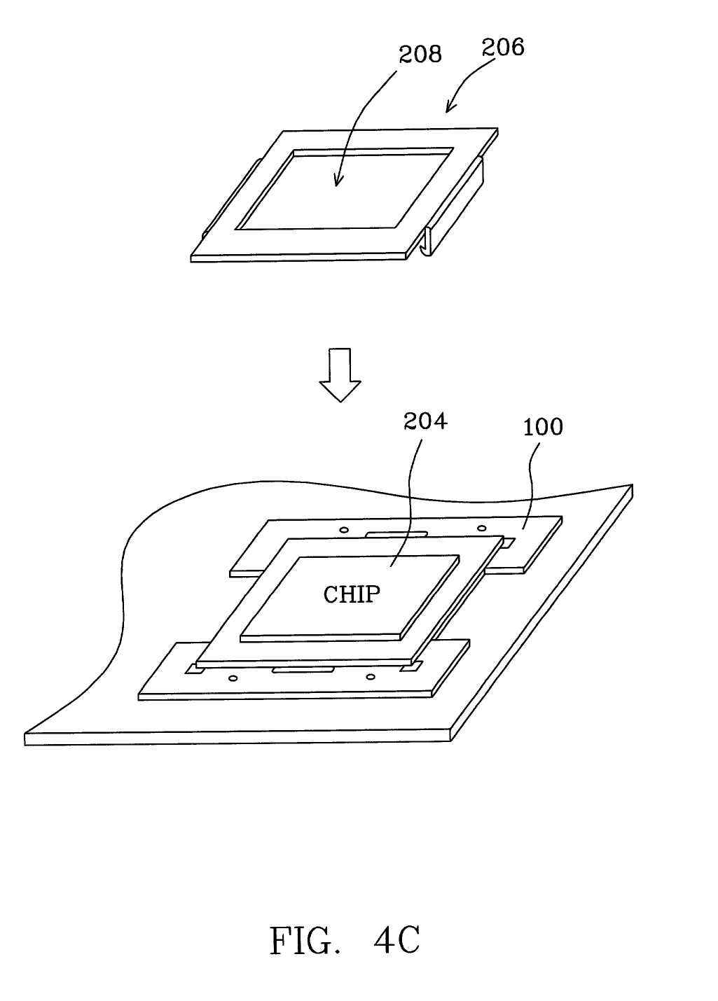

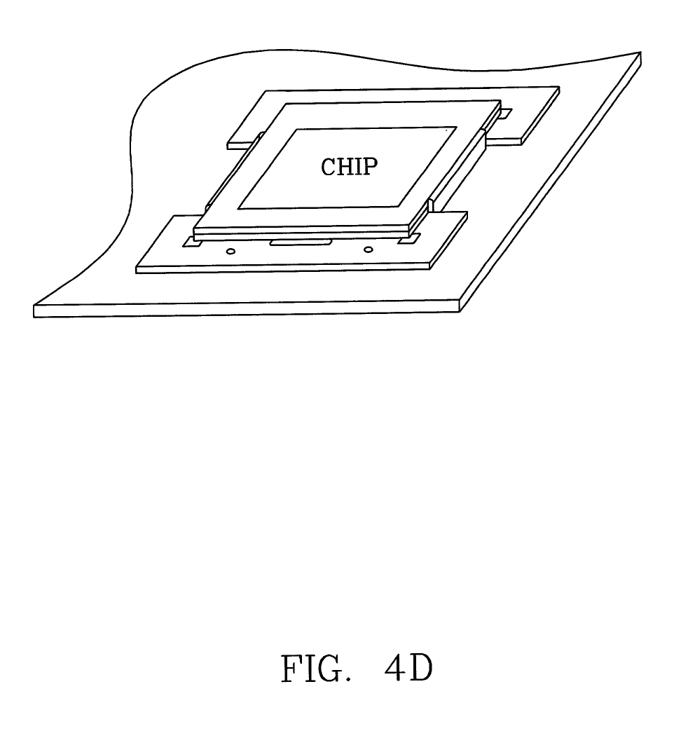

As shown in FIGS. 4A˜4D, the procedure of using the chip-testing socket having buckle-type fixing portion according to the embodiment of the invention is illustrated. The lines 404 for indicating the location to dispose the chip locate on the circuit board 402. Several bonding pads 406 electrically connected to the chip (not shown in FIG. 4A) are disposed inside the lines 404. When the chip 204 has been fabricated and needs to be tested, the chip-testing socket of the invention can be used to hold the chip 204 for testing. The method of using the chip-testing socket of the invention is described below.

Refer to FIG. 4A. First, the base 100 of the chip-testing socket of the invention is fixed on the circuit board 402 by disposing solder balls or applying solder paste on bonding pads 406 of the circuit board 402. The base 100 is fixed on the circuit board 402 by using surface mounting technology. It should be noted that because the base 100 has several windows, user can recognize the location of the region line 404 so that the base 100 can be attached on the circuit board 402 accurately as shown in lower portion of FIG. 2. In FIG. 4B, after the base 100 is fixed on the circuit board 402, the chip 204 is then flipped to contact the base 100, as shown in lower portion of FIG. 4C. After that, the buckle-type fixing means 206 is put on the base 100 and is pressed downwards. During the process of pressing downwards the buckle-type fixing portion 206, the pair of elastic side boards 210A and 210B bend outward until the buckles 212 of the elastic side boards 210A and 210B hook up the base 110. Consequently, the buckle-type fixing portion 206 connects to the base 100 and the chip 204 is held between the buckle-type fixing portion 206 and the base 100, as shown in FIG. 4D. With the presence of the opening 208 of the buckle-type fixing portion 206, the chip-testing socket having the buckle-type fixing portion 206 is particularly suitable for probing test from the back side during chip testing.

Similarly, the method of using the chip-testing socket of the invention having the cover-type fixing portion 214 is described below. Refer to FIG. 2B. First, in the same way, the base 100 is fixed on the circuit board 402. Next, the cover-type fixing portion 214 is fixed on the base 100 by screws, for example. After that, the chip 204 is placed in the cover-type fixing portion 214 so that the chip 204 connects to the base 100 electrically. Then, the cover 218 of the cover-type fixing portion 214 is closed and chip testing proceeds.

Although the base 100 of the embodiment of the invention includes the upper-layer 102, the middle-layer 104, and the lower-layer 106, it does not limit the invention. All kinds of bases in which the pin probes can fix are within the scope of the invention. Furthermore, the above-mentioned cover 218 of the cover-type fixing portion 214 can also have an opening when necessary.

When the chip-testing socket of the invention is put into use, the base is first fixed on the circuit board, and then the buckle-type fixing portion or the cover-type fixing portion is fixed on the base. Because of the several viewing windows for positioning the base, high positioning accuracy can be achieved easily. Moreover, because the base is fixed on the circuit board by using surface mount technology, re-layouting a new circuit board for chip testing, as is used conventionally, is not necessary. The cost and fabricating time can be reduced. Besides, by using elastic pin probes, the pin probe ends of the chip-testing socket of the invention will be kept on the same plane. Thus, contact error is avoided. Therefore, the accuracy of chip testing by applying the chip-testing socket is improved substantially.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A chip-testing socket using surface mount technology for holding a ball grid array (BGA) chip to be tested, the chip-testing socket comprising:
a base having a plurality of pin probes electrically connected to the circuit board, wherein the base could be disposed on the circuit board by using surface mount technology; and
a fixing portion for fixing the chip on the base wherein the fixing portion can be disposed to the base in a removable way.

2. A chip-testing socket according to claim 1, wherein the pin probes are elastic pin probes.

3. A chip-testing socket according to claim 2, wherein the elastic pin probe has an upper segment and a lower segment, the upper segment is put into the lower segment and is separated from the lower segment by an elastomer.

4. A chip-testing socket according to claim 3, wherein the upper segment of the pin probe has a concave pin probe tip and a stick-like part, the concave pin probe tip brings perfect connection between the elastic pin probe and a convex electrode of the BGA chip, and the stick-like part connects to the concave pin probe tip.

5. A chip-testing socket according to claim 4, wherein the pin probe lower segment has a ring projecting part and a tube part which connects to the ring projecting part, the ring projecting part is used for fixing the pin probe in the base, the tube part is employed to receive the stick-like part and the elastomer, the elastomer locates between the stick-like part and the tube part and plays a role as a buffer, and the elastomer shortens when the elastic pin probe is pressed.

6. A chip-testing socket according to claim 5, wherein the base comprises a first substrate, a second layer, and a third layer, which have a plurality of first holes, second holes, and third holes respectively, the diameter of the stick-like part is smaller than the ring projecting part, and the diameter of the ring projecting part is larger than the tube part, and the diameters of the first, second, and third holes are slightly larger than the diameters of the stick-like part, the ring projecting part, and the tube part respectively,
wherein the elastic pin probes are embedded in the base after the tube part, the ring projecting part, and the stick-like part are inserted in the third, second, and first hole respectively.

7. A chip-testing socket according to claim 1, wherein the fixing portion is a buckle-type fixing portion which has an opening and a pair of elastic side boards with buckles,
the elastic side boards bend outward until the buckles hook up a bottom surface of the base, when pressing downwards the buckle-type fixing portion toward the base.

8. A chip-testing socket according to claim 1, wherein the fixing portion is a cover-type fixing portion comprising a cover and a fixing portion body which has a cavity, the cover connects to the fixing portion body rotationally, and the chip can be held within the cavity, thus the chip connects to the base electrically after the fixing portion body is fixed on the base.

9. A chip-testing socket according to claim 8, wherein the cover-type fixing portion can be fixed on the base by tightening screws on the cover-type fixing portion and the base.

10. A chip-testing socket according to claim 1, the chip-testing socket further comprising a plurality of windows for positioning to a circuit board.

11. A chip-testing socket using surface mount technology for holding a ball grid array (BGA) chip to be tested, the chip-testing socket comprising:
a base having a plurality of elastic pin probes electrically connected to the circuit board, wherein the base could be disposed on the circuit board by using surface mount technology.

12. A chip-testing socket according to claim 11, wherein the chip-testing socket further comprising:
a fixing portion for fixing the chip on the base wherein the fixing portion can be disposed to the base in a removable way.

13. A chip-testing socket according to claim 12, wherein the fixing portion is a buckle-type fixing portion which has an opening and a pair of elastic side boards with buckles,
wherein during the process of pressing downwards the buckle-type fixing portion toward the base, the pair of elastic side boards bend outward until the buckles hook up a bottom surface of the base.

14. A chip-testing socket according to claim 12, wherein the fixing portion is a cover-type fixing portion comprising a cover and a fixing portion body which has a cavity, the cover connects to the fixing portion body rotationally, and the chip can be held within the cavity, thus the chip connects to the base electrically after the fixing portion body is fixed on the base.

15. A chip-testing socket according to claim 14, wherein the cover-type fixing portion can be fixed on the base by tightening screws on the cover-type fixing portion and the base.

16. A chip-testing socket according to claim 11, wherein each of the elastic pin probe has an upper segment and a lower segment, the upper segment is put into the lower segment and is separated from the lower segment by an elastomer.

17. A chip-testing socket according to claim 16, wherein the pin probe upper segment has a concave pin probe tip and a stick-like part, the concave pin probe tip brings perfect connection between the elastic pin probe and a convex electrode of the BGA chip, and the stick-like part connects to the concave pin probe tip.

18. A chip-testing socket according to claim 17, wherein the lower segment of pin probe has a ring projecting part and a tube part which connects to the ring projecting part, the ring projecting part is used for fixing the pin probe in the base, the tube part is employed to receive the stick-like part and the elastomer, the elastomer locates between the stick-like part and the tube part and plays a role as a buffer, and the elastomer shortens when the elastic pin probe is pressed.

19. A chip-testing socket according to claim 18 wherein the base comprises a first layer, a second layer, and a third layer, which have a plurality of first holes, second holes, and third holes respectively, the diameter of the stick-like part is smaller than the ring projecting part, and the diameter of the ring projecting part is larger than the tube part, and the diameters of the first, second, and third hole are slightly larger than the diameters of the stick-like part, the ring projecting part, and the tube part respectively,
wherein the elastic pin probes are embedded in the base after the tube part, the ring projecting part, and the stick-like part are inserted in the third, second, and first hole respectively.

20. A chip-testing socket according to claim 11, the chip-testing socket further comprising a plurality of windows for positioning to a circuit board.

21. An elastic pin probe which is disposed in a base for holding a chip, the elastic pin probe comprising:
a pin probe upper segment has a concave pin probe tip and a stick-like part, the concave pin probe tip brings perfect connection between the elastic pin probe and a convex electrode of the chip, and the stick-like part connects to the concave pin probe tip; and
a pin probe lower segment, the pin probe upper segment is put into the pin probe lower segment and is separated from the pin probe lower segment by an elastomer.

22. A chip-testing socket according to claim 21, wherein the pin probe lower segment has a ring projecting part and a tube part which connects to the ring projecting part, the ring projecting part is used for fixing the pin probe in the base, the tube part is employed to receive the stick-like part and the elastomer, the elastomer locates between the stick-like part and the tube part and plays a role as a buffer, and the elastomer shortens when the elastic pin probe is pressed.

23. A chip-testing socket according to claim 22 wherein the base comprises a first layer, a second layer, and a third layer, which have a plurality of first holes, second holes, and third holes respectively, the diameter of the stick-like part is smaller than the ring projecting part, and the diameter of the ring projecting part is larger than the tube part, and the diameters of the first, second, and third hole are slightly larger than the diameters of the stick-like part, the ring projecting part, and the tube part respectively,
wherein the elastic pin probes are embedded in the base after the tube part, the ring projecting part, and the stick-like part are inserted in the third, second, and first hole respectively.
